(19) United States
(12) Patent Application Publication
(10) Pub. No.: US 2025/0217557 A1
(43) Pub. Date: Jul. 3, 2025

(54) SYSTEMS AND PROCESSES FOR AUTOMATING GAS LIFT DESIGN

(71) Applicant: SAUDI ARABIAN OIL COMPANY, Dhahran (SA)

(72) Inventors: Muhammad Daanyal, Ras Tanura (SA); Ammal F. Al-Anazi, Dammam (SA); Cleavant J. Flippin, Ras Tanura (SA); Suhail A. Samman, Riyadh (SA)

(73) Assignee: SAUDI ARABIAN OIL COMPANY, Dhahran (SA)

(21) Appl. No.: 18/396,819

(22) Filed: Dec. 27, 2023

(51) Int. Cl. G06F 30/28; E21B 21/08; E21B 43/12

(52) U.S. Cl. CPC G06F 30/28; E21B 21/08; E21B 43/123; E21B 2200/20

(57) ABSTRACT

Methods and systems include obtaining well data using a well monitoring system, using a well design system, and defining a digital twin. The digital twin represents the gas well. The method and systems include transferring well data from the well monitoring system to the digital twin. The method and systems include determining an analysis of well data and identifying a gas lift design from the analysis.

### BACKGROUND

Hydrocarbon fluids are often found in hydrocarbon reservoirs located in porous rock formations far below the earth's surface. Production wells may be drilled to extract the hydrocarbon fluids from the hydrocarbon reservoirs. Often, hydrocarbon fluids are able to flow naturally to the surface through production wells because the pressure within the reservoir is sufficient to flow the hydrocarbon fluids to the surface. However, as the reservoir pressure becomes depleted, or is naturally a reservoir with low-pressure, forms of “artificial lift’ may be utilized to produce the hydrocarbon fluids. Gas lift is a form of artificial lift.

Gas lift uses a source of high-pressure gas to lower the density of or “lift” the hydrocarbon fluids to the surface. Gas lift systems use an external source of gas which is injected into tubing located in the production well. One external source may be the hydrocarbon reservoir. The gas mixes with the hydrocarbon fluids in the tubing. This reduces the density of the hydrocarbon fluids until the mixture becomes light enough to flow using the available reservoir pressure. Gas lift systems may need a gas lift design for planning the gas lift system before deployment in a production well.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In some aspects, the techniques described herein relate to a method for automating valve selection for a gas well. The method may include obtaining well data using a well monitoring system. The method may include, using a well design system, defining a digital twin, wherein the digital twin represents the gas well. The method may include transferring well data from the well monitoring system to the digital twin. The method may include determining an analysis of well data and identifying a gas lift design from the analysis.

In some aspects, the techniques described herein relate to a system for automating valve selection for a gas well. The system may include a well monitoring system configured to obtain well data from the gas well. The system may include a well design system configured to define a digital twin, wherein the digital twin represents the gas well. The system may include a well design system configured to transfer well data from the well monitoring system to the digital twin. The system may include a well design system configured to determine an analysis of well data and identify a gas lift design from the analysis.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1 shows an exemplary hydrocarbon reservoir in accordance with one or more embodiments.

FIG. 2 shows an exemplary well site in accordance with one or more embodiments.

FIG. 3 shows a gas lift system in accordance with one or more embodiments.

FIG. 4A-4B show an inflow control valve in an open and in a closed position in accordance with one or more embodiments.

FIG. 5 shows an injection pressure operated gas lift valve in accordance with one or more embodiments.

FIG. 6 shows a flowchart in accordance with one or more embodiments.

FIG. 7 shows a flowchart in accordance with one or more embodiments.

FIG. 8 depicts a computer in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements.

It is to be understood that the singular forms “a,” “an,” and “the” include plural referents unless the context clearly dictates otherwise.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that one or more of the steps shown in the flowchart may be omitted, repeated, and/or performed in a different order than the order shown. Accordingly, the scope disclosed herein should not be considered limited to the specific arrangement of steps shown in the flowchart.

Although multiple dependent claims are not introduced, it would be apparent to one of ordinary skill that the subject matter of the dependent claims of one or more embodiments may be combined with other dependent claims.

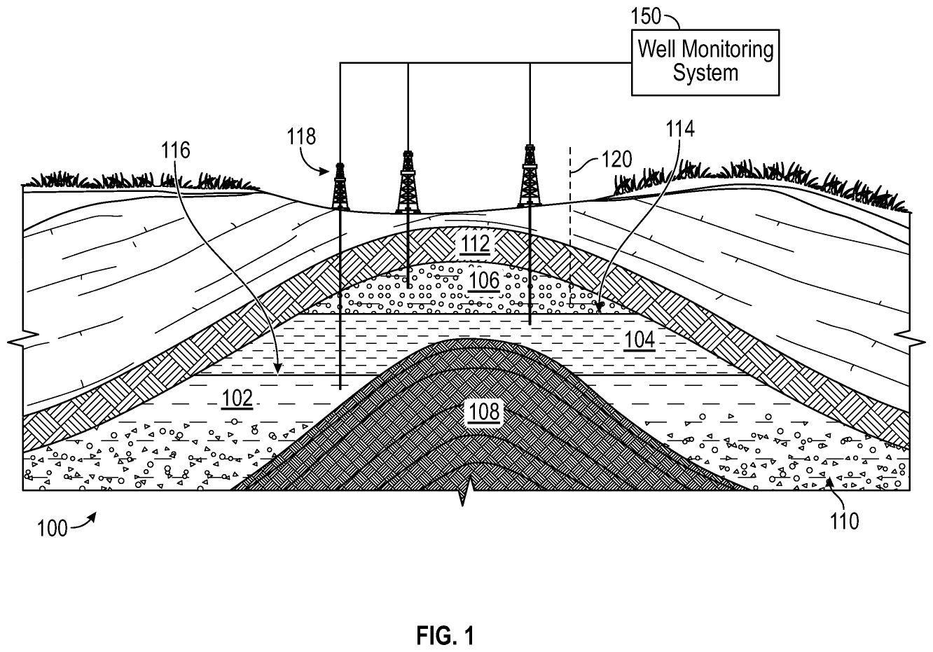

In the following description of FIGS. 1-7, any component described with regard to a figure, in various embodiments disclosed herein, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment which may be implemented in addition to, in conjunction with, or in place of the embodiments described with regard to a corresponding like-named component in any other figure.

Methods and systems are disclosed herein for automating valve selection. In one or more embodiments, the system for automating valve selection may determine, using a plurality of well and reservoir parameters, an analysis that identifies a gas lift design for a gas lift system. The well design system defines a digital twin that takes well data and case results as inputs to identify the gas lift designs. The automated system provides users with continuous monitoring, evaluation, optimization, and recommendations for gas lift systems and gas lift designs to potentially maximize hydrocarbon production from wells. In particular, in one or more embodiments, the methods and systems disclosed herein allow users to potentially optimize gas lift of production fluids within the well to potentially increase production rates.

FIG. 1 shows an exemplary reservoir (100) having water (102), oil (104), and gas (106). Conventional reservoirs (100), such as the one depicted in FIG. 1, have a source formation (108), a reservoir formation (110), and a cap rock (112). The source formation (108) is a formation rich in organic matter that, over time, is heated sufficiently to form hydrocarbon fluids such as gas (106) and oil (104). Oil (104) and gas (106) then migrate from the source formation (108) to a more porous and permeable rock called the reservoir formation (110). Due to the inherent nature of these subsurface fluids, gas (106) settles above oil (104) and oil (104) settles above water (102) in the reservoir (100). Therefore, there are various “contacts” within the reservoir (100) that distinguish locations of different subsurface fluids.

The gas oil contact (GOC) (114) is the location or “surface”, in the reservoir (100), above which predominantly gas (106) occurs and below which predominately oil (104) occurs. The gas (106) that accumulates above the GOC (114) may be called a gas cap or a gas cap reservoir. The oil water contact (OWC) (116) is the location or “surface,” in the reservoir (100), above which predominantly oil (104) occurs and below which predominately water (102) occurs. One or more wells of the well system may be drilled into the reservoir (100) to gather data, produce hydrocarbon fluids, and/or treat the formation such as the reservoir formation (110). Each well may be an exploration well, a production well, or an injection well. Production and injection wells, drilled into similar reservoirs (100) such as oil and/or gas reservoirs, typically target the oil (104) as the primary hydrocarbon fluid being produced and may inject water (102) to balance reservoir (100) pressure as reservoir (100) pressure declines as oil is produced. Injection wells may also inject chemicals into the formation to treat the formation and help produce oil (104). The production wells may produce water (102) and gas (106) as secondary fluids.

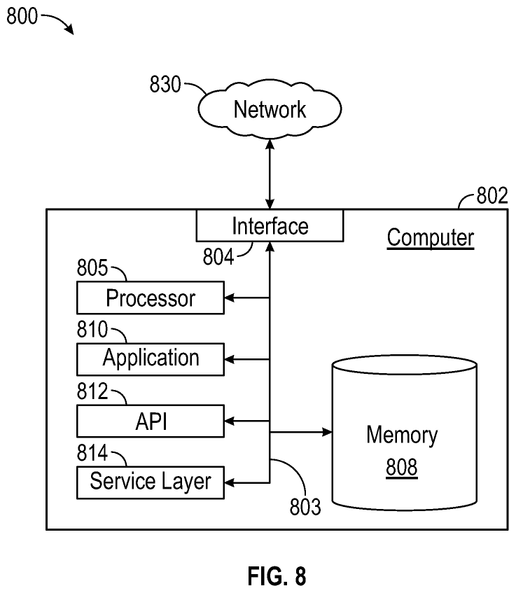

FIG. 1 depicts a well system (118) in accordance with one or more embodiments. The well system (118) may comprise one or more well sites that may be utilized to produce hydrocarbon fluids in the reservoir formation (110). In general, a well system may be configured in a myriad or ways. Therefore, the well system (118) is not intended to be limiting with respect to the particular configuration of the well system (118), well sites and/or well equipment. The well system (118) may include a well monitoring system (150). The well monitoring system (150) may use measurement devices that may continuously measure the conditions within the well site (200) such as pressure measurements. In one or more embodiments, the monitoring system may include a computer system (800) that may include the same or similar to that of computer (802) as described in FIG. 8 and accompanying description. The measurements may be transmitted to the well monitoring system (150). In one or more embodiments, the well system (118) may include a well plan (120). Well plans may be for future wells to produce additional hydrocarbon fluids within the reservoir (100).

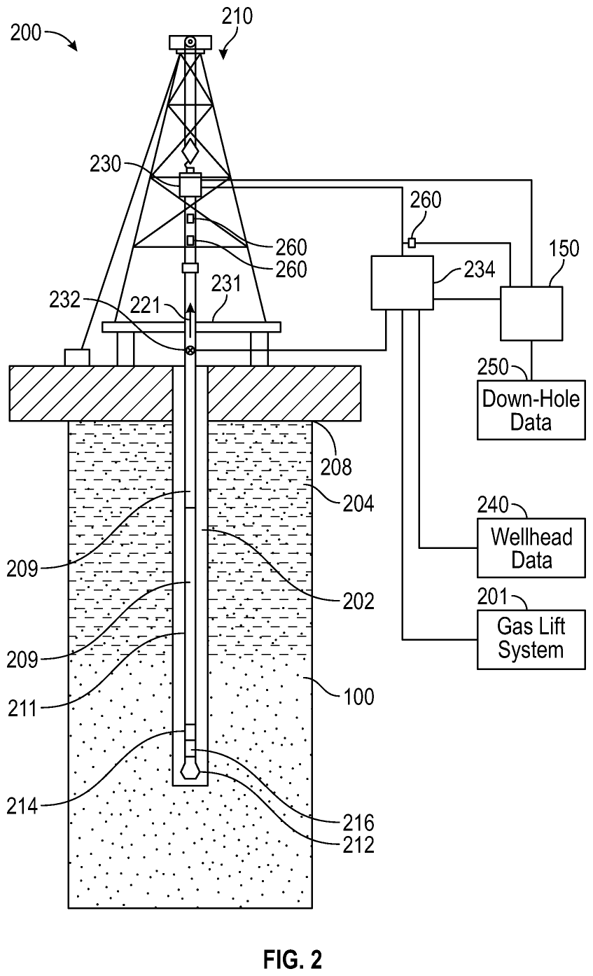

FIG. 2 shows an exemplary well site (200) in accordance with one or more embodiments. In general, well sites may be configured in a myriad of ways. Therefore, the well site (200) is not intended to be limiting with respect to the particular configuration of the production equipment. The well site (200) may include a well (210) such as a production well, an injection well, and/or an exploration well. The well site (200) may include the reservoir (100) located adjacent to a subsurface formation (204). The well site (200) is depicted as being on land having a platform floor (231). In other examples, the well site (200) may be offshore. The reservoir formation (110) may include a porous or fractured rock formation that resides underground, beneath the earth's surface (hereafter “surface”) (208). The reservoir formation (110) may include different layers of rock having varying characteristics, such as varying degrees of permeability, porosity, capillary pressure, and resistivity. In the case of the well (210) being operated as a production well, the well system (118) may facilitate the extraction of hydrocarbons (or “production”) from the reservoir (100).

In one or more embodiments, the well site (200) includes a wellbore (202), a well surface system (234). The well surface system (234) may control various operations of the well system (118), such as well production operations, well completion operations, well maintenance operations, and reservoir monitoring, assessment, and development operations. In one or more embodiments, the well surface system (234) includes a computer system (800) that is the same as or similar to that of computer (802) described below in FIG. 8 and the accompanying description.

The wellbore (202) may include a bored hole that extends from the surface (208) into a target zone of the reservoir (100). An upper end of the wellbore (202), terminating at or near the surface (208), may be referred to as the “up-hole” end of the wellbore (202), and a lower end of the wellbore (202), terminating in the reservoir formation (110), may be referred to as the “down-hole” end of the wellbore (202). The wellbore (202) may facilitate the circulation of drilling fluids during drilling operations, the flow of hydrocarbon production (hereafter “production”) (221) (e.g., oil and gas) from the reservoir formation (110) to the surface (208) during production operations, the injection of substances (e.g., water) into the reservoir formation (110) during injection operations, or the communication of monitoring devices (e.g., logging tools) into the reservoir formation (110) during monitoring operations (e.g., during in situ logging operations).

In one or more embodiments, during operation of the well site (200), the well surface system (234) collects and records wellhead data (240) for the well system (118). The wellhead data (240) may include, for example, a record of measurements of wellhead pressure (e.g., including flowing wellhead pressure), wellhead temperature (e.g., including flowing wellhead temperature), wellhead production rate over some or all of the life of the well (210), and water cut data. In one or more embodiments, the measurements are recorded in real-time, and are available for review or use within seconds, minutes or hours of the condition being sensed (e.g., the measurements are available within 1 hour of the condition being sensed). In such an embodiment, the wellhead data (240) may be referred to as “real-time” wellhead data (240). Real-time wellhead data (240) may enable an operator of the well system (118) to assess a relatively current state of the well system (118) and make real-time decisions regarding development of the well system (118) and the hydrocarbon fluid, such as on-demand adjustments in regulation of production flow from the well.

In accordance with one or more embodiments, during operation of the well site (200), the well monitoring system (150) may collect and record down-hole data for the well system (118). The well (210) may include down-hole measurement devices (216) to measure down-hole data (250) which may include, for example, down-hole temperature, down-hole pressure, and the like. The down-hole measurement devices (216) may be installed within the well for measuring well data. In one or more embodiments, the measurements are recorded in real-time, and are available for review or use within seconds, minutes or hours of the condition being sensed (e.g., the measurements are available within 1 hour of the condition being sensed). In such an embodiment, the down-hole data (250) may be referred to as “real-time” down-hole data (250). Real-time down-hole data (250) may enable an operator of the well system (118) to assess a relatively current state of the well system (118) and make real-time decisions regarding development of the well system (118) and the hydrocarbon fluid, such as on-demand adjustments in regulation of production flow from the well.

In one or more embodiments, the well (210) includes a casing string (211) installed in the wellbore (202). The casing string (211) may include one or more casing sections (209) installed in the wellbore (202). For example, the wellbore (202) may have a cased portion and an uncased (or “open-hole”) portion. The cased portion may include a portion of the wellbore having casing (e.g., casing pipe and casing cement) disposed therein. The uncased portion may include a portion of the wellbore not having casing disposed therein. In one or more embodiments, the casing includes an annular casing that lines the wall of the wellbore (202) to define a central passage that provides a conduit for the transport of tools and substances through the wellbore (202). For example, the central passage may provide a conduit for lowering logging tools into the wellbore (202), a conduit for the flow of production (221) (e.g., oil and gas) from the reservoir (100) to the surface (208), or a conduit for the flow of injection substances (e.g., water) from the surface (208) into the reservoir formation (110). In one or more embodiments, the well site (200) includes tubing (214) installed in the wellbore (202). The tubing (214) may provide a conduit for the transport of tools and substances through the wellbore (202). The tubing (214) may, for example, be disposed inside casing string (211). In such an embodiment, the tubing may provide a conduit for some or all of the production (221) (e.g., oil and gas) passing through the wellbore (202) and the casing string (211).

In one or more embodiments, the well surface system (234) includes a wellhead (230). The wellhead (230) may include a rigid structure installed at the “up-hole” end of the wellbore (202). The wellhead (230) may include structures for supporting (or “hanging”) a casing string (211) with one or more casing sections (209) and the tubing (214) extending into the wellbore (202). Production (221) may flow from the reservoir (100) through a completions system (212) that may include a downhole safety valve (DSV). The production may flow through the wellbore (202) and through the wellhead (230), after exiting the wellbore (202), including, for example, the casing string (211) and the tubing (214). In one or more embodiments, the well surface system (234) includes flow regulating devices that are operable to control the flow of substances into and out of the wellbore (202). For example, one or more production valves (232) may be fully opened to enable unrestricted flow of production (221) from the wellbore (202), the one or more production valve (232) may be partially opened to partially restrict (or “throttle”) the flow of production (221) from the wellbore (202), and the one or more production valves (232) may be fully closed to fully restrict (or “block”) the flow of production (221) from the wellbore (202), and through the well surface system (234).

In one or more embodiments, the wellhead (230) includes a choke assembly. For example, the choke assembly may include hardware with functionality for opening and closing the fluid flow through pipes in the well site (200). Likewise, the choke assembly may include a pipe manifold that may lower the pressure of fluid traversing the wellhead (230). As such, the choke assembly may include a set of high-pressure valves and at least two chokes. These chokes may be fixed or adjustable or a mix of both. Redundancy may be provided so that if one choke is taken out of service, the flow can be directed through another choke. In some embodiments, pressure valves and chokes are communicatively coupled to the well monitoring system (150). Accordingly, the well monitoring system (150) may be configured to obtain wellhead data (240) regarding the choke assembly as well as transmit one or more commands to components within the choke assembly in order to adjust one or more choke assembly parameters.

Continuing with FIG. 2, the well site (200) operates and maintains a hydraulic system to operate gas wellhead production valves and emergency shutdown zone valves (“ESDVs”) to ensure safe and reliable operations, in accordance with one or more embodiments. The well site (200) may include a supervisory control and data acquisition (“SCADA”) system (260). The SCADA system (260) is used to remotely operate the hydraulic valves. In one or more embodiments, the well site (200) communicates with the SCADA system (260) using wired and/or wireless data communication networks. The SCADA system (260) is a supervisory control system of computers, networked data communications and graphical user interfaces for gathering and analyzing real time data, such as the wellhead data (240) and other data collected by the well site (200). Specifically, the SCADA system (260) is used to monitor and control the well site (200). For example, various hydraulic valves, such as the one or more production valves (232) and/or other surface/subsurface valves of the well site (200), are remotely controlled using the SCADA system (260). In particular, each hydraulic valve can be closed and/or opened in response to a control signal sent from, or otherwise activated by the SCADA system (260). In one or more embodiments of the invention, the SCADA system (260) is implemented based on the computer system (802) that is the same as or similar to that of computer (802) described below in FIG. 8 and the accompanying description.

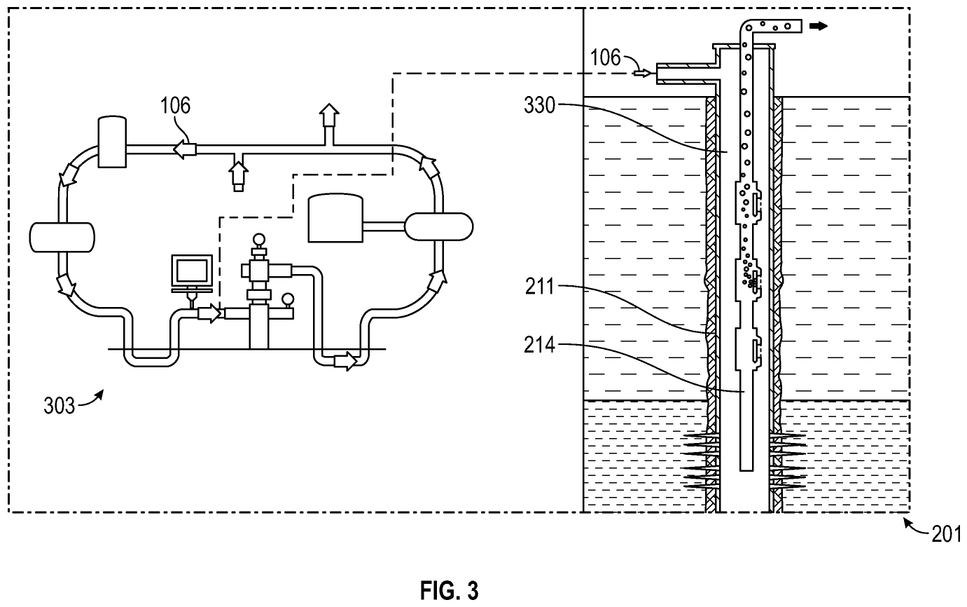

In accordance with one or more embodiments, the well surface system (234) may include a gas lift system (201), as shown in FIG. 3. In one or more embodiments, the gas lift system (201) may be a continuous gas lift system, wherein the continuous gas lift system is configured to operate continuously. The reservoir (100) may produce gas sufficient to supply the gas lift system (201) to be operated continuously. In accordance with one or more embodiments, the gas lift system (201) may be an intermittent gas lift system wherein the intermittent gas lift system is configured to operate intermittently. The reservoir (100) may produce gas sufficient to operate intermittently.

In general, gas lift systems may be configured in a myriad of ways. Therefore, the gas lift system (201) is not intended to be limiting with respect to the particular configuration of the gas lift equipment. Gas lift systems may use separated compressed gas (106) from a surface facility (303) and inject gas (106) from the surface facility (303) into the casing string (211) annulus (330) at a high injection pressure. The gas (106) enters the tubing (214), at the high pressure, and mixes with the fluid (such as oil (104)) located within the tubing (214). Additionally, the industry may use natural, or auto, gas lift systems which use gas (106) from a gas cap, or another form of formation gas (106).

The gas lift system (201), such as natural gas lift systems, are designed to produce the gas (106) along with the desired hydrocarbon fluids (such as oil (104)). This means that the gas (106) cannot be re-circulated, and gas (106) is continually being drawn from the gas cap, or the non-associated gas (106) reservoir formation (110) as depicted in FIG. 1, into the well (210). This depletes the gas cap/non-associated gas (106) reservoir formation (110) over time and eventually there may not be enough gas (106) to use for lifting the downhole fluids, such as oil (104). Thus, it is beneficial to have a gas lift system that has the ability to re-circulate the gas (106) back into the well system (118) without having surface separation and re-injection equipment. In accordance with one or more, embodiments disclosed herein may include a gas lift system, using in-situ gas (106) from a gas cap or other gas reservoir, where the gas (106) is able to be re-circulated into the system using downhole equipment.

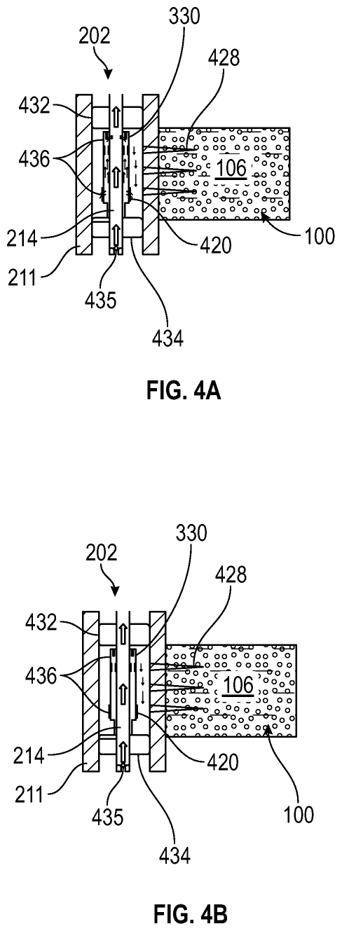

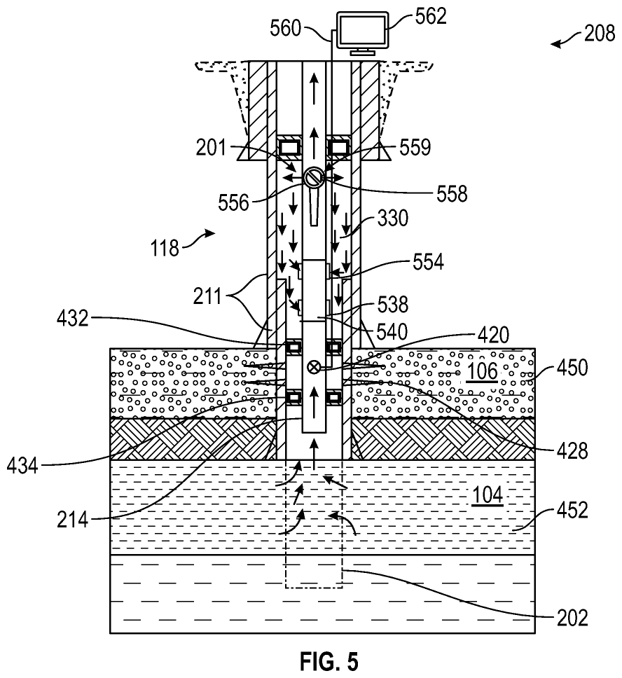

FIGS. 4A, 4B, and 5 depict operating components of the gas lift system (201), in accordance with one or more embodiments. In particular, FIGS. 4A and 4B depict an inflow control valve (“ICV”) (420) in an open position and a closed position. More specifically, FIG. 4A depicts the ICV (420), in the open position, installed in the tubing (214) deployed in a wellbore (202), and FIG. 4B depicts the ICV (420), in the closed position, installed in the tubing (214) deployed in the wellbore (202). The wellbore (202) has casing string (211) that supports the wellbore (202) and protects the wellbore (202) from an uncontrolled influx of subsurface fluids.

The casing string (211) may have a plurality of perforations (428) across a portion of the reservoir (100) containing gas (106) such that the gas (106) may exit the reservoir (100) and enter the annulus (330) located between the tubing (214) and the casing string (211). An upper packer (432) and a lower packer (434) are installed above and below the ICV (420) in order to isolate the gas (106) to that portion of the annulus (330). The upper packer (432) and the lower packer (434) may be any kind of packer known in the art.

The ICV (420) is installed across the portion of the reservoir (100) containing gas (106), as shown in FIGS. 4A and 4B, and the ICV (420) controls the flow of gas (106) into the system in which the ICV (420) is installed, such as the tubing (214). The ICV (420) may have pressure and temperature sensors. The ICV (420) may have a ball valve (435) or a flapper valve that prevents the gas (106) from flowing down the tubing (214). The ICV (420) may be controlled electrically through a cable that connects the ICV (420) to the surface and enables data transmission between the ICV (420) and the surface. The surface is any location outside of the wellbore (202) such as the Earth's surface, a data van, a control panel on the Earth's surface, etc.

In one or more embodiments, the ICV (420) may be controlled hydraulically though a hydraulic control line that connects the ICV (420) to the surface. The hydraulic control line is a conduit for hydraulic fluid that is able to control the ICV (420). When the ICV (420) is instructed to open, by a control panel or a computer processor either connected to the cable or the hydraulic control line, the ICV (420) shifts to reveal a plurality of channels (436), as depicted in FIG. 4A. The channels (436) allow the gas (106) to move from the annulus (330) into the tubing (214). When the ICV (420) is instructed to close, the ICV (420) shifts to close the channels (436), as depicted in FIG. 4B. This prevents the gas (106) from migrating from the annulus (330) into the tubing (214).

FIG. 5 depicts, in one or more embodiments, the gas lift system (201) which uses in situ gas (106), from a gas reservoir (450), to artificially lift oil (104), from an oil reservoir (452). The components of the gas lift system (201) depicted in FIG. 5 that are identical/similar to the components depicted in FIG. 4A to FIG. 5 are not re-described for purposes of readability and have the same functions described above. The gas lift system (201) is installed within the well (210) which is completed across the reservoir (100) such as the gas reservoir (450) and/or the oil reservoir (452).

The well (210) has casing string (211) or liner that supports the wellbore (202) and isolates the subsurface fluids. The casing string (211) or liner extends to a depth above the gas reservoir (450), and the wellbore (202) continues through the oil reservoir (452) with no casing or liner. The casing string (211) or liner is perforated with a plurality of perforations (428) across the gas reservoir (450) to allow gas (106) to enter the annulus (330) between the upper packer (432) and the lower packer (434).

In one or more embodiments, the casing string (211) or liner may extend through the oil reservoir (452), and the casing string (211) or liner may be perforated with a plurality of perforations (428) across the oil reservoir (452) to allow oil (104) to enter the casing string (211) or liner. The gas lift system (201) includes a tubing (214) that extends to a depth above the oil reservoir (452). The tubing (214) is a conduit for production fluids. The production fluids may be any fluids produced at the surface (208) such as oil (104), gas (106), or water.

The production fluids have a weight which is the combined density of the mixture of fluids. In one or more embodiments, the tubing (214) may extend to a depth within the oil reservoir (452). For the embodiment depicted in FIG. 5, the production fluid is oil (104) and the oil (104) flows from the oil reservoir (452) into the wellbore (202), into the casing string (211) or liner, and into the tubing (214). If the oil reservoir (452) has enough pressure, the oil (104) may flow up through the tubing (214) to be produced at the surface (208).

If the oil reservoir (452) does not have enough pressure to lift the weight of the oil (104) to the surface (208), then gas (106) is injected into the oil (104) to lower the weight of the oil (104) such that the combined weight of the oil (104) and gas (106) is lower than the pressure of the oil reservoir (452) and the production fluids and the injected gas (106) are able to flow through the tubing (214) using the pressure from the oil reservoir (452). The gas (106) is injected into the oil (104) using a combination of the ICV (420), an injection-pressure-operated (IPO) gas lift (GL) valve (538), other GL valves (554) such as orifice valves, and/or a gas-separator compressor turbine device (556). The gas lift system may include a tubing having a mandrel (540) configured to provide positioning of gas lift valves along the tubing string. The GL valve (538) may be installed in the mandrel (540).

The ICV (420) opens to allow gas (106) to enter the tubing (214) from the portion of the annulus (330) between the upper packer (432) and the lower packer (434). The gas (106) flows up the tubing (214) to be separated from any other production fluids that may be in the tubing (214) and compressed by the gas-separator compressor turbine device (556). The gas-separator compressor turbine device (556) injects the gas (106) into the portion annulus (330) located above the upper packer (432).

When the injection pressure in the annulus (330) reaches a predetermined pressure, the IPO GL valve (538) opens, and the gas (106) enters the tubing (214) through the IPO GL valve (538). There may be other GL valves (554) installed on the tubing (214) such as pressure actuated valves like production pressure operated (PPO) valves, differential pressure operated (DPO) valves, throttling valves, orifice valves, or pilot valves. The other GL valves (554) may also allow the injected gas (106) to enter the tubing (214) from the annulus (330).

The lighter weight of the gas (106), along with the injection pressure, helps to lower the weight of the production fluids and helps to lift the production fluids through the well (210) and to the surface (208). When the injected gas (106) reaches the height of the gas-separator compressor turbine device (556), the injected gas (106), along with any new gas (106) from the reservoir (100), such as a gas reservoir, is separated from the production fluids and the process is repeated. This process allows most of the gas (106) to be recycled meaning that the gas (106) from the reservoir (100) is continually recycled to help lift the production fluids.

There is at least one sensor (558) installed on the outlet (559) of the gas-separator compressor turbine device (556) that measures the volume of the gas (106) being injected into the annulus (330). The at least one sensor (558) may be upstream and/or downstream pressure and temperature sensors. Once the volume of gas (106) reaches a predetermined volume, the ICV (420) will close, and the production fluids may continue to flow due to the recycling of gas (106) through the gas-separator compressor turbine device (556).

When the volume of gas (106) being injected into the annulus (330) becomes lower than the pre-determined volume, the ICV (420) will open to allow more gas (106) to enter the tubing (214) from the gas reservoir (450). This process may be repeated as many times as required. In one or more embodiments, the amount of gas (106) needed to lift the production fluids may change over time and the predetermined volume of gas (106) injected into the annulus (330) may change as needed.

As depicted in FIG. 5, the ICV (420) is open and closed using at least one cable (560), electronically capable of transmitting data, connecting the ICV (420) to a control panel (562) at the surface (208). Instructions may come from the control panel (562) using an automated program or instructions may come from a person at the surface controlling the control panel (562). The ICV (420) may also be opened partially or completely for example, the ICV (420) may have ten “steps,” with step 0 being a 0% open position (referred to as a “fully closed” position), step 1 being a 10% open position, step 2 being a 20% open position, and so forth, with step 10 being a 100% open position (referred to as a “fully opened” position).

It is obvious to a person of ordinary skill in the art that the ICV (420) may be controlled using any means available in the art and is not limited to using a cable (560) or a hydraulic control line. Furthermore, it is obvious that the well completion design is not limited to the design depicted in FIG. 5, and any system that uses a gas-separator compressor turbine device (556) to recycle in-situ gas (106) for use in the gas lift system (201) and an ICV (420) to control the flow of the gas (106) from the reservoir (100) may be used without departing from the scope of this disclosure.

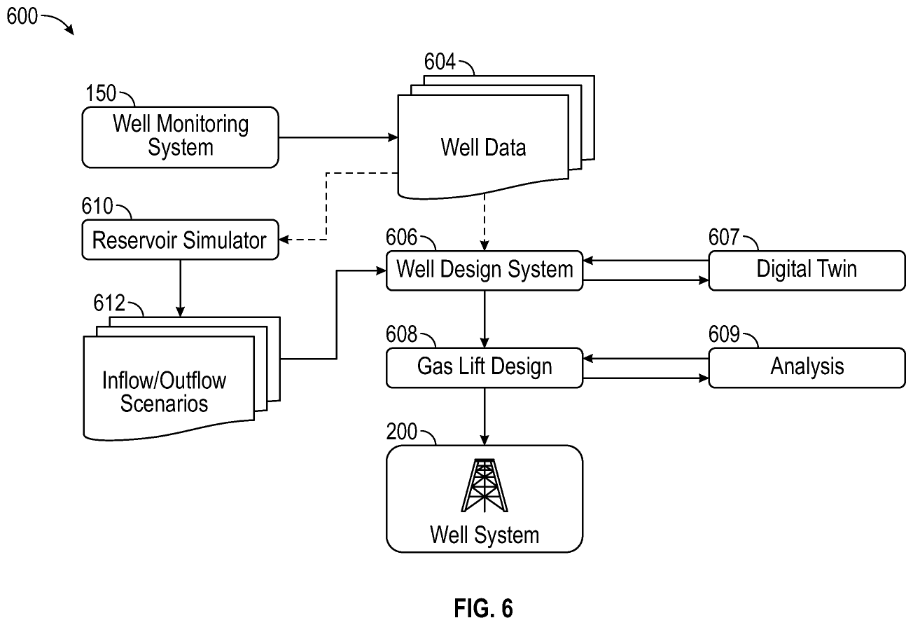

FIG. 6 illustrates a workflow in accordance with one or more embodiments. The workflow includes steps of acquiring well data such as wellhead data and/or down-hole data, processing the well data, forming one or more gas lift designs, optionally simulating the flow of fluids, including hydrocarbons, through the one or more reservoir simulations, the planning of boreholes including their surface position, trajectories, and targets, and the drilling of those boreholes, deployment of completions and gas lift systems. Although the steps in flowchart using the workflow are shown in sequential order, it will be apparent to one of ordinary skill in the art that some steps may be conducted in parallel, in a different order than shown, or may be omitted without departing form the scope of the invention.

In accordance with one or more embodiments, the system for automating valve selection (hereafter “selection system”) may comprise the well monitoring system (150) as described in the context of FIG. 1 and FIG. 2. The well monitoring system (150) may be configured to obtain and/or store well data (604) such as wellhead data and down-hole data as described in more detail in the context of FIG. 2 and FIG. 3. The well data (604) may include well logs obtained by monitoring devices (e.g., logging tools) into the reservoir formation (110) during monitoring operations (e.g., during in situ logging operations). Logging tools may include, but are not limited to, electrical, optical, radioactive, and acoustic logging tools. The various logging tools and measurement devices may transmit well data (604) by cable, or wirelessly to the well monitoring system (150).

The well data (604) may include well data measurements that are influenced by the reservoir properties such as reservoir temperature, reservoir pressure, porosity, permeability, and the like. The well data (604) may contain a wide variety of noises and distortion or may need depth matching of logging runs and does not in its unprocessed “raw” form display significant useful information about the reservoir and production fluids. The well data (604) may be processed to remove or attenuate noise and to correctly depth match logging runs. The well data (604) may include synthetic well logs generated and/or calculated from well measurements or geologic models. Geologic models may contain subsurface formation information such as structure, lithology, porosity, and the like. Geologic models may be formed from remote sensing data such as seismic and electrical data.

It will be appreciated by one of ordinary skill in the art that the well data (604) may be extremely large, typically occupying Gigabytes in size, and cannot, with current technology, be manipulated or “processed” without the assistance of a purpose configured well design system.

In one or more embodiments, the selection system may comprise a well design system (606). The well design system (606) may be configured to perform data gathering and/or data organizing. The well design system (606) may include hardware and software with functionality for facilitating data transfer and data analysis. The well design system (606) may use real-time algorithms based on data mining techniques. Data mining may be used for automating data gathering and/or data organizing. Data mining utilizes one or more databases such as the well data (604), and/or case results. Data mining techniques may include, but are not limited to, regression analysis, clustering analysis, neural networks, or combination thereof.

In one or more embodiments, the well design system (606) may include a computer system (800) that is the same as or similar to that of computer (802) described below in FIG. 8 and accompanying description. The well design system (606) may be configured with appropriate well data processing software and augmented with a number of purpose specific elements, such as high-speed buses connecting computer processing units (“CPUs”). Further the CPUs of the well design system (606) may be connected to a plurality of graphical processing units (“GPUs”) that perform many of the computationally intensive operations on the well data (604), banks of high-speed tape, or hard-drive, readers to read the data from storage, high-speed tape, or hard-drive writers to output final or intermediate results, and high-speed communication buses to connect these elements.

In accordance with one or more embodiments, the selection system may use a reservoir simulator (610) to develop inflow/outflow scenarios (612) by integrating well data (604), one or more geologic models, and well data (604) such as well logs, case scenarios, and the like. The inflow/outflow scenarios (612) may be used to estimate potential production from a well (210). The inflow/outflow scenarios (612) may be integrated with the one or more geologic models to develop a gas lift design (608). The gas lift design (608) may be used to estimate any hydrocarbon outflow performance improvement from using gas injected into the tubing (214). The gas lift design (608) may be implemented within the well system (118) as described in FIG. 2 and the accompanying description. The well system (118) may deploy the gas lift system (201) as described in FIG. 3 to FIG. 5 and the accompanying description. In some embodiments, the selection system may be configured to model inflow/outflow scenarios (612) and determine gas lift parameters.

In accordance with one or more embodiments, the well design system (606) may be configured to define a digital twin (607) wherein the digital twin (607) represents one or more wells such as the well (210) described in reference to FIG. 2. The well design system (606) may be configured to transfer well data (604) from the well monitoring system (150) to the digital twin (607). The digital twin (607) may include, but is not limited to, well data, completions data, inflow/outflow scenarios, and facilities data. Completions data may include, but is not limited to, completion type, perforation design, inflow/outflow capacity, completion depths, mandrel depths, tubing parameters, and completion intervals. Facilities data may include, but are not limited to, facility type, pressure limitations, and production capacity.

The digital twin (607) may be coupled with various systems for carrying out steps of the workflow (600) while utilizing the well data (604) transferred from the well monitoring system (150). For example, the various systems may include, but are not limited to, the well design system (606), the reservoir simulator (610) and the well monitoring system (150), The coupling may be static, dynamic, and the like. In one or more embodiments, the well design system (606) is configured to perform dynamic coupling and transfer the well data (604) such as, but are not limited to, reservoir pressure, productivity index, well completion details, and well surface systems data to the digital twin (607). Dynamic coupling may be between various systems for carrying out the steps of the workflow (600), such as between the digital twin and a data visualization system. The dynamic coupling may define a strength of association between the various systems. The data visualization system may be coupled with the digital twin, such that the data visualization system may receive gas lift designs that may include valve configurations and plot valve locations (e.g., valve and/or mandrel depths), and valve types along the gas lift design visually.

In one or more embodiments, the well design system (606) may be configured to determine an analysis (609) from the well data (604). The analysis (609) may determine a lifting point and a production rate on the basis of reservoir parameters, tubing and completion parameters, available gas-injection pressure and rate, and operating pressure. The analysis (609) may identify the gas lift design (608) based on a plurality of parameters such as, but is not limited to, reservoir parameters, well surface systems parameters, and/or gas lift design parameters. For example, the plurality of parameters may include production rates, GL valve types, GL valve sizes, port sizes, GL valve spacing, unloading valve requirements, and operating valve requirements.

GL valve types may include, but are not limited to, IPO valves (538), PPO valves, orifice valves and other GL valves as described in reference to FIG. 3 to FIG. 5. In one or more embodiments, the analysis (609) may utilize advanced analytics. Advanced analytics may include, but is not limited to, predictive modeling, machine learning algorithms, deep learning, process automation, other statistical methods, or combination thereof. Advanced analytics may be utilized to predict fluid flow scenarios during the life of the well and automate well design to account for fluid flow scenarios.

In accordance with one or more embodiments, the selection system may be configured to evaluate case results wherein the case results comprise one or more well histories. The well history may include, but is not limited to, a well's production data, completions data, gas injection rates, and reservoir properties. Production data may include, but are not limited to, hydrocarbon production flow rates, produced water flow rates, and water injection rates.

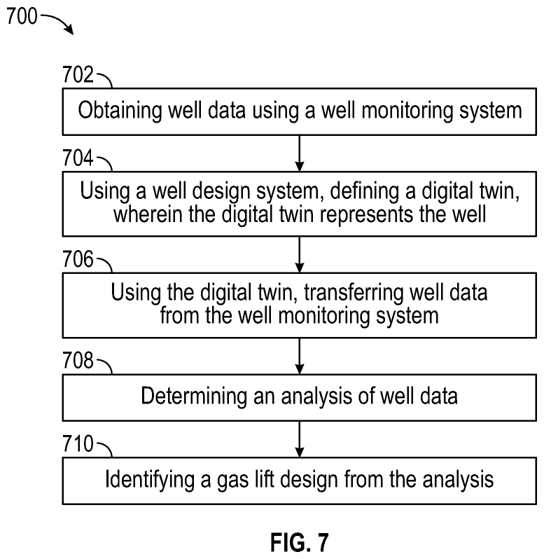

FIG. 7 depicts a flowchart in accordance with one or more embodiments. More specifically, FIG. 7 illustrates a method for automating gas lift design (hereafter “selection method”) (700) that uses a digital twin for modeling gas lift parameters. Further, one or more steps in FIG. 7 may be performed by one or more components as described in FIGS. 3-5. While the various steps in FIG. 7 are present and described sequentially, one of ordinary skill in the art will appreciate that some or all of the steps may be executed in different orders, may be combined, or omitted, and some or all steps may be executed in parallel. Furthermore, the steps may be performed actively or passively.

In step (702) in accordance with one or more embodiments, the selection method (700) may comprise, using the well monitoring system (150), obtaining well data (604). The selection method (700) may include obtaining well data (604) such as wellhead data and down-hole data as described in more detail in the context of FIG. 2 and FIG. 3. The well data (604) may include being obtained remotely and/or with logging tools. Remote sensing may include, but is not limited to, seismic, electrical, electromagnetic, magnetic, and gravity techniques. Logging tools may include, but are not limited to, electrical, acoustic, radioactive, and optical tools.

In step (704) in accordance with one or more embodiments, the selection method (700) may include, using the well design system (606), defining a digital twin (607) wherein the digital twin (607) represents one or more wells such as the well (210) described in reference to FIG. 2. The digital twin (607) may include well data (604), completions data, and well surface systems. In step (706) in some embodiments, the selection method (700) may include transferring well data (604) from the well monitoring system (150) to the digital twin (607). The selection method (700) may include coupling the digital twin (607) with various systems for carrying out steps of the workflow (600) while utilizing the well data (604) transferred from the well monitoring system (150). The coupling may include, but is not limited to, static coupling or dynamic coupling.

In step (708) in accordance with one or more embodiments, the selection method (700) may include determining the analysis (609) of well data (604). The selection method (700) may include determining a lifting point and production rate on the basis of reservoir parameters, tubing and completion parameters, available gas-injection pressure and rate, and operating pressure. In step (710) in accordance with some embodiments, the selection method (700) may include identifying the gas lift design (608) from the analysis (609) of the well data (604). The selection method (700) may also include identifying the gas lift design (608) based on the plurality of parameters such as, but is not limited to, reservoir parameters, well surface systems parameters, and/or gas lift design parameters as described in reference to FIG. 6. In one or more embodiments, the selection method (700) may include utilizing advanced analytics for performing the analysis (609). Advanced analytics may include well production simulations such as well flow rates, and/or production rates. Well production simulations may include simulations with and without gas lift. Gas lift designs may include valve performance and stability analysis, such as valve configurations, plot valve locations (e.g., valve and/or mandrel depths), and/or valve types.

In one or more embodiments, the selection method (700) may include a continuous gas lift system (201). The well may produce gas from the reservoir (100) sufficient to supply the gas lift system (201) so that the gas lift system (201) may operate continuously. In accordance with one or more embodiments, the gas lift system (201) may be an intermittent gas lift system wherein the intermittent gas lift system is configured to operate intermittently. The reservoir (100) may produce gas sufficient to operate intermittently.

In accordance with one of more embodiments, the selection method (700) may include the gas lift system (201) wherein the gas lift valve comprises, but is not limited to, the IPO lift valve, the PPO valve, and/or the orifice valve.

In accordance with one or more embodiments, the method may include deploying the gas lift system (201) as in reference to FIG. 3 to FIG. 5. The gas lift system (201) may be disposed within the well. The gas lift system (201) may be based on the gas lift design (608). The gas lift system (201) may include tubing configured to be a conduit for production fluids. The gas lift system (201) may include the ICV (420), a gas-separator compressor turbine device, at least one sensor fixed to an outlet of the gas-separator compressor turbine device, and a gas lift valve installed within the tubing.

In accordance with one or more embodiments, the selection method (700) may include evaluating case results wherein the case results comprise one or more well histories. Using the well design system (606), the analysis (609) may utilize well histories.

FIG. 8 is a block diagram of a computer (802) used to provide computational functionalities associated with described algorithms, methods, functions, processes, flows, and procedures as described in the instant disclosure, according to an implementation. The computer (802) is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (802) may include a computer that includes an input device, such as a keypad, keyboard, touch screen, or other device that can accept user information, and an output device that conveys information associated with the operation of the computer (802), including digital data, visual, or audio information (or a combination of information), or a graphical user interface (“GUI”.)

The computer (802) can serve in a role as a client, a network component, a server, a database or other persistency, or any other component (or a combination of roles) of a computer for performing the subject matter described in the instant disclosure. The computer (802) is communicably coupled with a network (830). In some implementations, one or more components of the computer (802) may be configured to operate within environments, including cloud-computing-based, local, global, or other environment (or a combination of environments).

At a high level, the computer (802) is an electronic computing device operable to receive, transmit, process, store, or manage data and information associated with the described subject matter. According to some implementations, the computer (802) may also include or be communicably coupled with an application server, e-mail server, web server, caching server, streaming data server, business intelligence (BI) server, or other server (or a combination of servers).

The computer (802) can receive requests over network (830) from a client application (for example, executing on another computer (802) and responding to the received requests by processing the said requests in an appropriate software application. In addition, requests may also be sent to the computer (802) from internal users (for example, from a command console or by other appropriate access method), external or third-parties, other automated applications, as well as any other appropriate entities, individuals, systems, or computers.

Each of the components of the computer (802) can communicate using a system bus (803). In some implementations, any, or all of the components of the computer (802), both hardware or software (or a combination of hardware and software), may interface with each other or the interface (804) (or a combination of both) over the system bus (803) using an application programming interface (API) (812) or a service layer (814) (or a combination of the API (812) and service layer (814). The API (812) may include specifications for routines, data structures, and object classes. The API (812) may be either computer-language independent or dependent and refer to a complete interface, a single function, or even a set of APIs. The service layer (814) provides software services to the computer (802) or other components (whether or not illustrated) that are communicably coupled to the computer (802).

The functionality of the computer (802) may be accessible for all service consumers using this service layer. Software services, such as those provided by the service layer (814), provide reusable, defined business functionalities through a defined interface. For example, the interface may be software written in JAVA, C++, or other suitable language providing data in extensible markup language (XML) format or another suitable format. While illustrated as an integrated component of the computer (802), alternative implementations may illustrate the API (812) or the service layer (814) as stand-alone components in relation to other components of the computer (802) or other components (whether or not illustrated) that are communicably coupled to the computer (802). Moreover, any or all parts of the API (812) or the service layer (814) may be implemented as child or sub-modules of another software module, enterprise application, or hardware module without departing from the scope of this disclosure.

The computer (802) includes an interface (804). Although illustrated as a single interface (804) in FIG. 8, two or more interfaces (804) may be used according to particular desires or implementations of the computer (802). The interface (804) is used by the computer (802) for communicating with other systems in a distributed environment that are connected to the network (830). Generally, the interface (804) includes logic encoded in software or hardware (or a combination of software and hardware) and operable to communicate with the network (830). More specifically, the interface (804) may include software supporting one or more communication protocols associated with communications such that the network (830) or interface's hardware is operable to communicate physical signals within and outside of the computer (802).

The computer (802) includes at least one computer processor (805). Although illustrated as a single computer processor (805) in FIG. 8, two or more processors may be used according to particular desires or particular implementations of the computer (802). Generally, the computer processor (805) executes instructions and manipulates data to perform the operations of the computer (802) and any algorithms, methods, functions, processes, flows, and procedures as described in the instant disclosure.

The computer (802) also includes a memory (808) that holds data for the computer (802) or other components (or a combination of both) that can be connected to the network (830). For example, memory (808) may include a database storing data and/or processing instructions consistent with this disclosure. According to further embodiments, memory may correspond, for example, to memory (808) where the computer (802) has been implemented as a digital controller. Although illustrated as a single memory (808) in FIG. 8, two or more memories may be used according to particular desires and/or implementations of the computer (802) and the described functionality. While memory (808) is illustrated as an integral component of the computer (802), in alternative implementations, memory (808) can be external to the computer (802).

An application (810) is an algorithmic software engine providing functionality according to particular desires and/or particular implementations of the computer (802), particularly with respect to functionality described in this disclosure. For example, the application (810) can serve as one or more components, modules, applications, etc. Further, although illustrated as a single application (810), the application (810) may be implemented as multiple applications (810) on the computer (802). In addition, although illustrated as integral to the computer (802), in alternative implementations, the application (810) can be external to the computer (802).

There may be any number of computers (802) associated with, or external to, the computer system (800) containing computer (802), each computer (802) communicating over network (830). Further, the term “client,” “user,” and other appropriate terminology may be used interchangeably as appropriate without departing from the scope of this disclosure. Moreover, this disclosure contemplates that many users may use one computer (802), or that one user may use multiple computers (802).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A method for automating valve selection for a gas well, the method comprising:
obtaining well data using a well monitoring system; and
using a well design system,
defining a digital twin, wherein the digital twin represents the gas well; and
using the digital twin:
transferring well data from the well monitoring system;
determining an analysis of well data; and
identifying a gas lift design from the analysis.

2. The method of claim 1, further comprising:
evaluating case results wherein the case results comprise one or more well histories.

3. The method of claim 1, further comprising:
coupling dynamically the digital twin with the gas lift design.

4. The method of claim 1, further comprising:
modeling of inflow/outflow scenarios; and
determining gas lift parameters.

5. The method of claim 1, wherein the analysis comprises data mining.

6. The method of claim 1, further comprising;
deploying a gas lift system, disposed within the gas well and based on the gas lift design, the gas lift system comprising:
tubing configured to be a conduit for production fluids;
an inflow control valve;
a gas-separator compressor turbine device;
at least one sensor fixed to an outlet of the gas-separator compressor turbine device; and
a gas lift valve installed within the tubing;
wherein the inflow control valve, the gas-separator compressor turbine device, and the gas lift valve, are configured to be installed within the tubing.

7. The method of claim 6, wherein the gas lift system comprises a continuous gas lift system.

8. The method of claim 6, wherein the gas lift valve comprises an injection pressure operated lift valve.

9. The method of claim 6, wherein the gas lift valve comprises an orifice valve.

10. A system for automating valve selection for a gas well, the system comprising:
a well monitoring system configured to obtain well data from the gas well; and
a well design system configured to,
define a digital twin, wherein the digital twin represents the gas well; and
using the digital twin:
transfer well data from the well monitoring system;
determine an analysis of well data; and
identify a gas lift design from the analysis.

11. The system of claim 10, wherein the well design system is configured to, evaluate case results wherein the case results comprise one or more well histories.

12. The system of claim 10, wherein the well design system is configured to, couple dynamically the digital twin with the gas lift design.

13. The system of claim 10, wherein the well design system is configured to,
model of inflow/outflow scenarios; and
determine gas lift parameters.

14. The system of claim 10, wherein the analysis comprises data mining.

15. The system of claim 10, further comprising:
a gas lift system comprising:
tubing configured to be a conduit for production fluids having a weight;
an inflow control valve;
a gas-separator compressor turbine device;
at least one sensor fixed to an outlet of the gas-separator compressor turbine device; and
a gas lift valve installed within the tubing;
wherein the inflow control valve, the gas-separator compressor turbine device, and the gas lift valve, are configured to be installed within the tubing.

16. The system of claim 15, wherein the gas lift system comprises a continuous gas lift system.

17. The system of claim 15, wherein the gas lift valve comprises an injection pressure operated lift valve.

18. The system of claim 15, wherein the gas lift valve comprises an orifice valve.
